(19) United States
(12) Patent Application Publication
(10) Pub. No.: US 2026/0322360 A1
(43) Pub. Date: Oct. 15, 2026

(54) CONTROL APPARATUS

(71) Applicant: Mitsubishi Electric Corporation, Chiyoda-ku, Tokyo (JP)

(72) Inventors: Tetsuya SHIGEEDA, Tokyo (JP); Shinsuke SHIBATA, Tokyo (JP)

(73) Assignee: Mitsubishi Electric Corporation, Chiyoda-ku, Tokyo (JP)

(21) Appl. No.: 19/485,326

(22) PCT Filed: Jun. 9, 2023
(86) PCT No.: PCT/JP2023/021482

§ 371 Date: Nov. 18, 2025

(51) Int. Cl. H03K 3/01; H03K 17/687

(52) U.S. Cl. CPC H03K 3/01; H03K 17/687

(57) ABSTRACT

A control apparatus includes: two first power supply lines; two second power supply lines; a control circuit to which first power is supplied from a power supply circuit via the two first power supply lines; a first non-contact relay having a first input/output end, the first power being supplied to one of the first input/output end, second power being supplied to another of the first input/output end from the power supply circuit via the two second power supply lines; and a second non-contact relay having a second input/output end, the second power being supplied to one of the second input/output end, third power being supplied to another of the second input/output end, an external component being connected to the another of the second input/output end.

### FIELD

The present disclosure relates to a control apparatus including a non-contact relay.

### BACKGROUND

Conventionally, a control apparatus to be used on a train or the like uses a non-contact relay, such as a photocoupler, so as to insulate one circuit from another circuit. For example, Patent Literature 1 discloses a technique of outputting an output from a semiconductor direct current (DC)/DC converter as an operation signal information digital signal to a signal reading unit via a photocoupler, which is a non-contact relay, in an external condition input circuit to be used on a train.

### CITATION LIST

### Patent Literature

Patent Literature 1: Japanese Patent Application Laid-open No. 2014-075660

### SUMMARY OF INVENTION

### Problem to be Solved by the Invention

A portion between a primary side and a secondary side of a photocoupler, that is, a portion between a light emitting diode side and a light-receiving element side, can be regarded as being coupled by a parasitic capacitance present inside the photocoupler, a parasitic capacitance present in a wiring path, and the like. When such a circuit is used, due to a parasitic capacitance present near the photocoupler, noise applied to the secondary side of the photocoupler returns to a vehicle body after flowing through the primary side of the photocoupler, or noise applied to the primary side of the photocoupler returns to the vehicle body after flowing through the secondary side of the photocoupler. Therefore, a circuit configuration in which a control circuit is connected to a noise source via a photocoupler has a problem in that the control circuit may malfunction due to noise flowing in the control circuit via the photocoupler.

The present disclosure has been made in view of the above, and an object of the present disclosure is to provide a control apparatus capable of reducing inflow of noise to a desired path via parasitic capacitance while including a non-contact relay.

### Means to Solve the Problem

In order to solve the above-described problems and achieve the object, a control apparatus according to the present disclosure includes: two first power supply lines, an inductor being disposed on each of the two first power supply lines; two second power supply lines; a control circuit to which first power is supplied from a power supply circuit via the two first power supply lines; a first non-contact relay having a first input end and a first output end, the first power being supplied to one of the first input end and the first output end from the power supply circuit via the two first power supply lines, second power being supplied to another of the first input end and the first output end from the power supply circuit via the two second power supply lines; and a second non-contact relay having a second input end and a second output end, the second power being supplied to one of the second input end and the second output end from the power supply circuit via the two second power supply lines, third power being supplied to another of the second input end and the second output end, an external component being connected to the another of the second input end and the second output end.

### Effects of the Invention

The control apparatus of the present disclosure has an effect of being capable of reducing inflow of noise to a desired path via parasitic capacitance while including a non-contact relay.

### BRIEF DESCRIPTION OF DRAWINGS

FIG. 1 is a diagram illustrating an exemplary configuration of a control apparatus according to a first embodiment.

FIG. 2 is a diagram illustrating an image of parasitic capacitances present in the control apparatus according to the first embodiment.

FIG. 3 is a diagram illustrating an image of a circuit where a load connected to the control apparatus according to the first embodiment serves as a noise source of common-mode noise.

FIG. 4 is a diagram illustrating exemplary paths through which common-mode noise flows in the control apparatus according to the first embodiment.

FIG. 5 is a diagram illustrating an exemplary configuration of a control apparatus according to a second embodiment.

FIG. 6 is a diagram illustrating an image of parasitic capacitances present in the control apparatus according to the second embodiment.

FIG. 7 is a diagram illustrating an image of a circuit where a switch connected to the control apparatus according to the second embodiment serves as a noise source of common-mode noise.

FIG. 8 is a diagram illustrating exemplary paths through which common-mode noise flows in the control apparatus according to the second embodiment.

### DESCRIPTION OF EMBODIMENTS

Hereinafter, control apparatuses according to embodiments of the present disclosure will be described in detail with reference to the drawings.

### First Embodiment

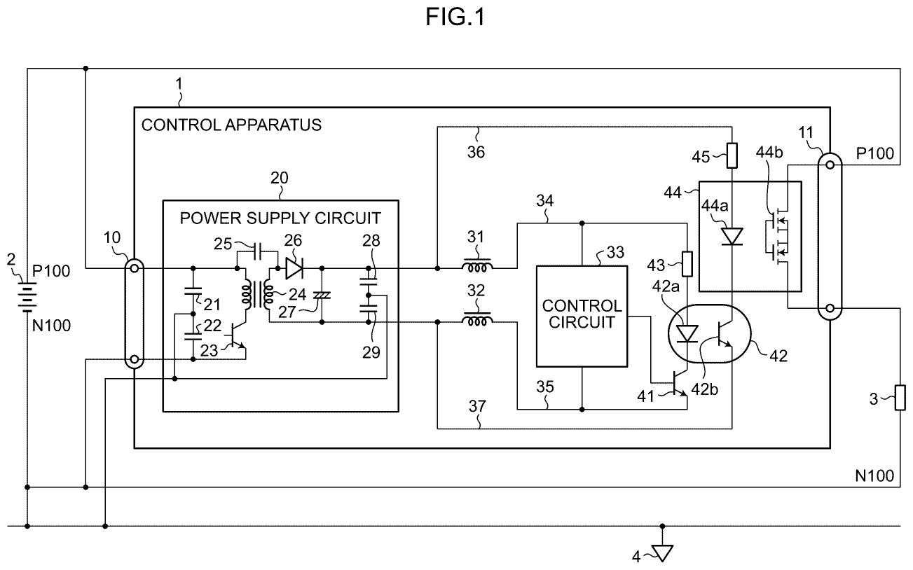

FIG. 1 is a diagram illustrating an exemplary configuration of a control apparatus 1 according to a first embodiment. The control apparatus 1 is a digital output (DO) circuit to be used on a train (not illustrated) or the like. The control apparatus 1 is connected to a vehicle power supply 2 and a load 3. The control apparatus 1 controls supply of electric power from the vehicle power supply 2 to the load 3 and controls operation of the load 3 under the control of a control circuit 33. The control apparatus 1 includes connecting portions 10 and 11, a power supply circuit 20, a 34 on which an inductor 31 is disposed, a first power supply line 35 on which an inductor 32 is disposed, the control circuit 33, second power supply lines 36 and 37, a transistor 41, a photocoupler 42, resistors 43 and 45, and a photo metal-oxide-semiconductor field-effect transistor (MOSFET) relay (hereinafter, referred to as a PhotoMOS relay) 44. The power supply circuit 20 includes Y-capacitors 21, 22, 28, and 29, a switching element 23, a transformer 24, capacitors 25 and 27, and a diode 26. In the following description, the photocoupler 42 may be referred to as a first non-contact relay, and the PhotoMOS relay 44 may be referred to as a second non-contact relay.

The control apparatus 1 is connected to a positive electrode P100 of the vehicle power supply 2 at one end of the connecting portion 10, and is connected to a negative electrode N100 of the vehicle power supply 2 at another end of the connecting portion 10. In addition, the control apparatus 1 is connected to the positive electrode P100 of the vehicle power supply 2 at one end of the connecting portion 11, and is connected to the negative electrode N100 of the vehicle power supply 2 at another end of the connecting portion 11 via the load 3. The another end of the connecting portion 11 is an OUTPUT terminal. The load 3 is an external component one end of which is connected to the another end of the connecting portion 11 of the control apparatus 1 and another end of which is connected to the negative electrode N100 of the vehicle power supply 2. The load 3 is, for example, an onboard device to be installed on a train (not illustrated) or the like. Note that a connection point between the Y-capacitors 21 and 22, a connection point between the Y-capacitors 28 and 29, the negative electrode N100 of the vehicle power supply 2, the another end of the connecting portion 10 of the control apparatus 1, and the another end of the load 3 are connected to a frame ground (FG) 4. The FG 4 is, for example, a vehicle body of a train (not illustrated).

In the control apparatus 1, the power supply circuit 20 is a DC/DC converter that converts the voltage of electric power supplied from the vehicle power supply 2 into a voltage for driving the control circuit 33, the photocoupler 42, and the PhotoMOS relay 44. For example, as a countermeasure against switching noise caused by switching performed by the switching element 23, the power supply circuit 20 includes the Y-capacitor 21 between a positive side of power supply input and the FG 4, the Y-capacitor 22 between a negative side of the power supply input and the FG 4, the capacitor 25 between a primary side and a secondary side of the transformer 24, the Y-capacitor 28 between a positive side of the power supply output and the FG 4, and the Y-capacitor 29 between a negative side of the power supply output and the FG 4. In the present embodiment, the power supply circuit 20 has a general configuration. Therefore, a detailed description of operation of the power supply circuit 20 will be omitted. Note that the configuration of the power supply circuit 20 is not limited to the exemplary configuration illustrated in FIG. 1. The power supply circuit 20 may have a configuration different from the configuration illustrated in FIG. 1 as long as the power supply circuit 20 includes a Y-capacitor.

The inductors 31 and 32 are disposed on the first power supply lines 34 and 35, respectively. Specifically, as illustrated in FIG. 1, the inductor 31 is disposed on the first power supply line 34, and the inductor 32 is disposed on the first power supply line 35. That is, the control apparatus 1 includes the two first power supply lines 34 and 35 on each of which an inductor is disposed. The first power supply lines 34 and 35 on which the inductors 31 and 32 are disposed, respectively, are power supply lines that supply first power from the power supply circuit 20 to the control circuit 33 and a first input end of the photocoupler 42 to which a light-emitting diode 42a is connected.

Note that no inductor is disposed on the second power supply lines 36 and 37. That is, the control apparatus 1 includes the two second power supply lines 36 and 37 on which no inductor is disposed. The second power supply lines 36 and 37 are power supply lines that supply second power from the power supply circuit 20 to a first output end of the photocoupler 42 and a second input end of the PhotoMOS relay 44. A light-receiving element 42b is connected to the first output end. A light-emitting diode 44a is connected to the second input end.

The control circuit 33 is supplied with the first power from the power supply circuit 20 via the two first power supply lines 34 and 35. The control circuit 33 controls the on/off of the transistor 41 by controlling a base current of the transistor 41. As a result of turning on and off the transistor 41, the control circuit 33 can control operation of the load 3.

The on/off of the transistor 41 is controlled by the control circuit 33. By turning on the transistor 41 under the control of the control circuit 33, it is possible to conduct the first power to the light-emitting diode 42a at the first input end of the photocoupler 42 and cause the light-emitting diode 42a to emit light. The resistor 43 is a resistor for adjusting the magnitude of the first power supplied from the power supply circuit 20. The resistor 45 is a resistor for adjusting the magnitude of the second power supplied from the power supply circuit 20.

The photocoupler 42 includes the light-emitting diode 42a and the light-receiving element 42b. In addition, the photocoupler 42 has the first input end and the first output end. The light-emitting diode 42a is connected to the first input end. The light-receiving element 42b is connected to the first output end. As illustrated in FIG. 1, the light-emitting diode 42a at the first input end is supplied with the first power from the power supply circuit 20 via the two first power supply lines 34 and 35, and the light-receiving element 42b at the first output end is supplied with the second power from the power supply circuit 20 via the two second power supply lines 36 and 37.

The PhotoMOS relay 44 includes the light-emitting diode 44a and a light-receiving element 44b. Furthermore, the PhotoMOS relay 44 has the second input end and a second output end. The light-emitting diode 44a is connected to the second input end. The light-receiving element 44b is connected to the second output end. As illustrated in FIG. 1, the light-emitting diode 44a at the second input end is supplied with the second power from the power supply circuit 20 via the two second power supply lines 36 and 37, and the light-receiving element 44b at the second output end is supplied with third power from the vehicle power supply 2, and is connected to the load 3 serving as an external component.

In the present embodiment, the control circuit 33 can control conduction of the first power in the light-emitting diode 42a at the first input end of the photocoupler 42 by controlling the on/off of the transistor 41 as described above. The control circuit 33 conducts the first power to the light-emitting diode 42a at the first input end of the photocoupler 42, so that the light-emitting diode 42a at the first input end of the photocoupler 42 emits light. Thus, the second power can be conducted to the light-receiving element 42b at the first output end of the photocoupler 42. The light-receiving element 42b at the first output end of the photocoupler 42 and the light-emitting diode 44a at the second input end of the PhotoMOS relay 44 are connected in series. Therefore, the control circuit 33 can conduct the second power to the light-emitting diode 44a at the second input end of the PhotoMOS relay 44 by conducting the second power to the light-receiving element 42b at the first output end of the photocoupler 42. The control circuit 33 conducts the second power to the light-emitting diode 44a at the second input end of the PhotoMOS relay 44, so that the light emitting diode 44a at the second input end of the PhotoMOS relay 44 emits light. Therefore, the third power from the vehicle power supply 2 can be conducted to the light-receiving element 44b at the second output end of the PhotoMOS relay 44. Then, the control circuit 33 causes the third power from the vehicle power supply 2 to be conducted to the light-receiving element 44b at the second output end of the PhotoMOS relay 44, so that the third power is supplied from the vehicle power supply 2 to the load 3. Thus, the control circuit 33 can control operation of the load 3.

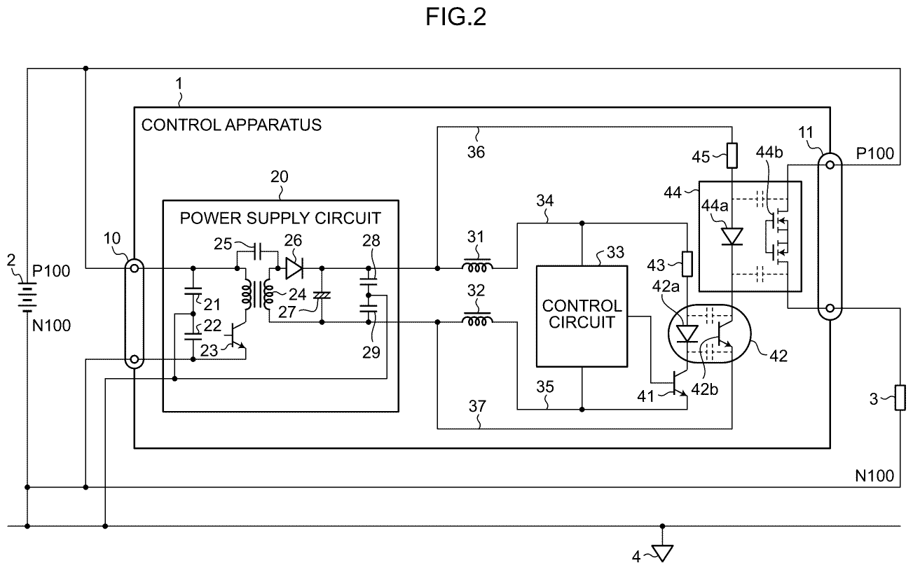

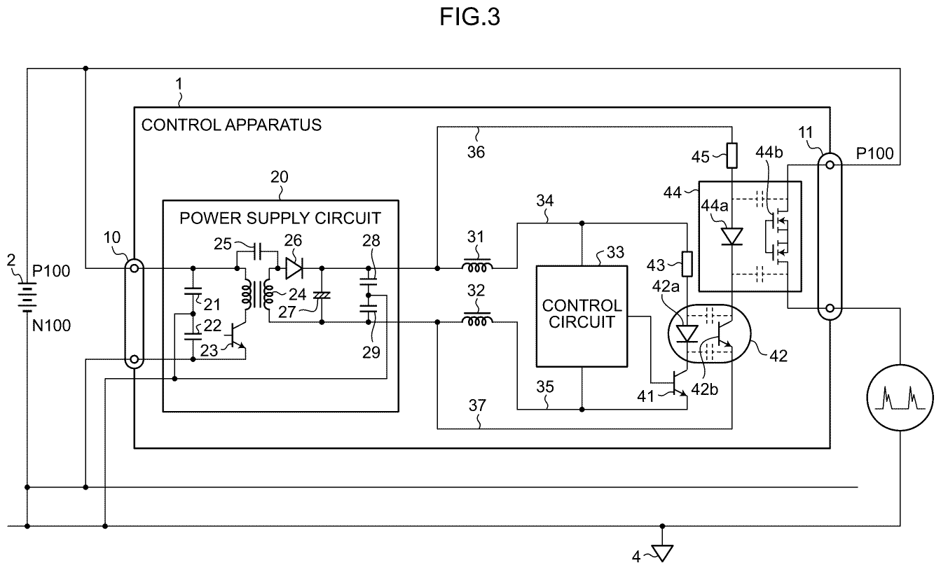

Here, as described in the section “Background”, it is assumed that parasitic capacitances are present inside the photocoupler 42, the PhotoMOS relay 44, and the like. FIG. 2 is a diagram illustrating an image of parasitic capacitances present in the control apparatus 1 according to the first embodiment. The control apparatus 1 illustrated in FIG. 2 is different from the control apparatus 1 illustrated in FIG. 1 in that parasitic capacitances have been added to the inside of the photocoupler 42 and the PhotoMOS relay 44 in FIG. 2. Meanwhile, in fact, a parasitic capacitance is also present between wires, between a wire and a housing, and the like. In a case where parasitic capacitances are present inside the control apparatus 1 as illustrated in FIG. 2, when common-mode noise is generated at the load 3, that is, when the load 3 serves as a noise source of common-mode noise, a loop is generated in which common-mode noise flows inside the control apparatus 1 and returns from the FG 4 to the noise source. FIG. 3 is a diagram illustrating an image of a circuit where the load 3 connected to the control apparatus 1 according to the first embodiment serves as a noise source of common-mode noise. As illustrated in FIG. 3, when the load 3 serves as a noise source of common-mode noise, the noise source can be regarded as a circuit configuration in which one end is connected to the another end of the connecting portion 11 of the control apparatus 1 as with the load 3, but another end is connected to the FG 4. In such a case, when common-mode noise flows to the control circuit 33, there is a possibility that the control circuit 33 may malfunction and affect the control of the load 3.

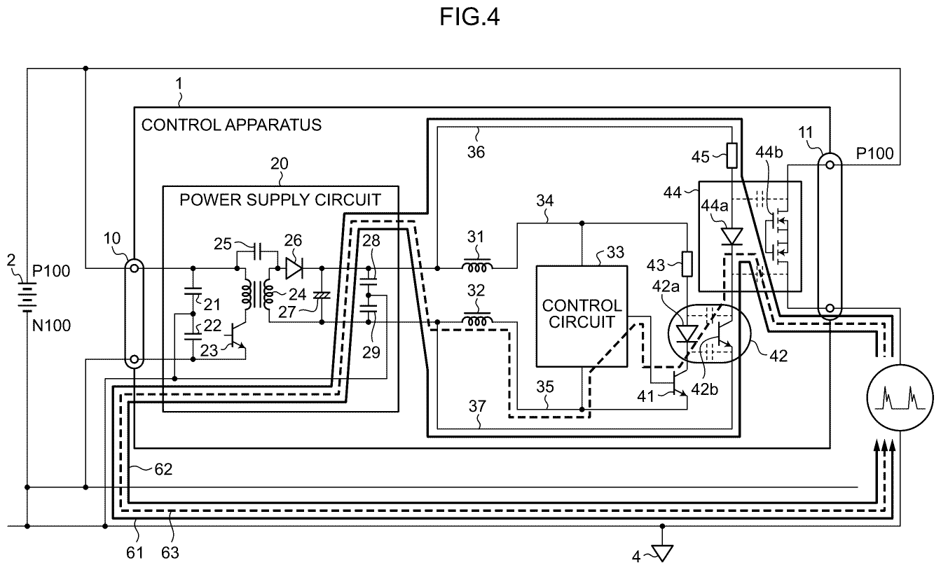

However, in the present embodiment, the inductors 31 and 32 are disposed on the first power supply lines 34 and 35, respectively, through which the first power is supplied from the power supply circuit 20 to the control circuit 33. Since the inductors 31 and 32 are disposed on the first power supply lines 34 and 35, respectively, impedances of the first power supply lines 34 and 35 are larger than impedances of the second power supply lines 36 and 37 on which no inductor is disposed. Therefore, even in a case where common-mode noise flows inside the control apparatus 1, more common-mode noise flows through the second power supply lines 36 and 37 having smaller impedances, than through the first power supply lines 34 and 35 to which the control circuit 33 is connected. FIG. 4 is a diagram illustrating exemplary paths 61 to 63 through which common-mode noise flows in the control apparatus 1 according to the first embodiment. The paths 61 to 63 through which common-mode noise flows in the control apparatus 1 have been added to FIG. 3 to obtain FIG. 4. From the relationship between the respective impedances of the power supply lines provided inside the control apparatus 1 as described above, it is considered that most of common-mode noise flows through the paths 61 and 62 and hardly flows through the path 63.

The path 61 is a path from the noise source to the noise source via the connecting portion 11, parasitic capacitances of the PhotoMOS relay 44, the resistor 45, the second power supply line 36, the Y-capacitor 28, the connection point between the Y-capacitors 28 and 29, and the FG 4. The path 62 is a path from the noise source to the noise source via the connecting portion 11, a parasitic capacitance of the PhotoMOS relay 44, the light-receiving element 42b of the photocoupler 42, the second power supply line 37, the Y-capacitor 29, the connection point between the Y-capacitors 28 and 29, and the FG 4. The path 63 is a path from the noise source to the noise source via the connecting portion 11, the parasitic capacitance of the PhotoMOS relay 44, parasitic capacitances of the photocoupler 42, the transistor 41, the control circuit 33, the first power supply line 35, the inductor 32, the Y-capacitor 29, the connection point between the Y-capacitors 28 and 29, and the FG 4. Note that the path 63 may be a path from the noise source to the noise source via the connecting portion 11, the parasitic capacitance of the PhotoMOS relay 44, the parasitic capacitances of the photocoupler 42, the transistor 41, the control circuit 33, the first power supply line 34, the inductor 31, the Y-capacitor 28, the connection point between the Y-capacitors 28 and 29, and the FG 4. Note that the paths 61 to 63 illustrated in FIG. 4 are examples, and parasitic capacitances may also be present between wires, between a wire and the vehicle body, and the like.

As described above, in a case where common-mode noise flows through the control apparatus 1 where the load 3 serves as a noise source, a total amount of common-mode noise flowing through the two second power supply lines 36 and 37 is larger than a total amount of common-mode noise flowing through the two first power supply lines 34 and 35.

Note that, in the present embodiment, the photocoupler 42 is used as the first non-contact relay, and the PhotoMOS relay 44 is used as the second non-contact relay, but the first non-contact relay and the second non-contact relay are not limited thereto. The control apparatus 1 may use a PhotoMOS relay as the first non-contact relay and a photocoupler as the second non-contact relay. In addition, the control apparatus 1 may use a photocoupler as each of the first non-contact relay and the second non-contact relay, or may use a PhotoMOS relay as each of the first non-contact relay and the second non-contact relay. Furthermore, the control apparatus 1 can also use a mechanical relay as the first non-contact relay and the second non-contact relay. As described above, the control apparatus 1 can use a photocoupler, a PhotoMOS relay, or a mechanical relay as the first non-contact relay and the second non-contact relay.

As described above, according to the present embodiment, the control apparatus 1 supplies the first power from the power supply circuit 20 to the control circuit 33 and the light-emitting diode 42a at the first input end of the photocoupler 42 serving as the first non-contact relay via the first power supply line 34, on which the inductor 31 is disposed, and the first power supply line 35, on which the inductor 32 is disposed. In addition, the control apparatus 1 supplies the second power from the power supply circuit 20 to the light-receiving element 42b at the first output end of the photocoupler 42 serving as the first non-contact relay and to the light-emitting diode 44a at the second input end of the PhotoMOS relay 44 serving as the second non-contact relay via the second power supply lines 36 and 37. As a result, even when common-mode noise is generated at the load 3 serving as a noise source and the common-mode noise flows inside the control apparatus 1, the control apparatus 1 can cause more common-mode noise to flow through the second power supply lines 36 and 37 than through the first power supply lines 34 and 35 to which the control circuit 33 is connected. Thus, malfunction of the control circuit 33 due to common-mode noise can be reduced. That is, while including the non-contact relays, the control apparatus 1 can reduce the inflow of noise into a desired path via a parasitic capacitance, specifically, into the first power supply lines 34 and 35 to which the control circuit 33 is connected.

### Second Embodiment

In the first embodiment, the DO circuit has been specifically described as an example of the control apparatus 1. In a second embodiment, a digital input (DI) circuit will be specifically described as an example of the control apparatus.

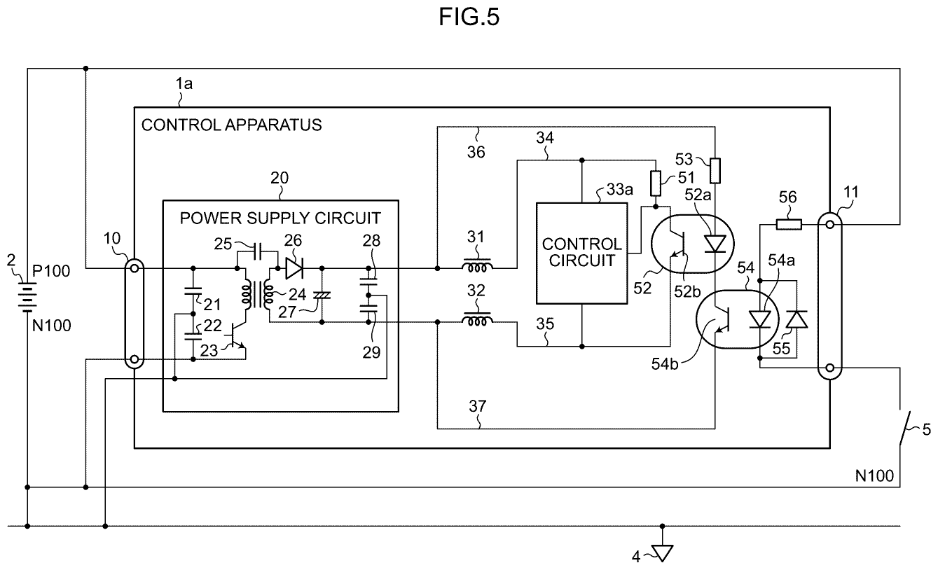

FIG. 5 is a diagram illustrating an exemplary configuration of a control apparatus 1a according to a second embodiment. The control apparatus 1a is a DI circuit to be used on a train (not illustrated) or the like. The control apparatus 1a is connected to the vehicle power supply 2 and a switch 5. A control circuit 33a in the control apparatus 1a acquires information on operation received by the switch 5. The control apparatus 1a includes the connecting portions 10 and 11, the power supply circuit 20, the first power supply line 34 on which the inductor 31 is disposed, the first power supply line 35 on which the inductor 32 is disposed, the control circuit 33a, the second power supply lines 36 and 37, resistors 51, 53, and 56, photocouplers 52 and 54, and a diode 55. The configuration of the power supply circuit 20 of the second embodiment illustrated in FIG. 5 is similar to the configuration of the power supply circuit 20 of the first embodiment illustrated in FIG. 1 and the like. In the following description, the photocoupler 52 may be referred to as a first non-contact relay, and the photocoupler 54 may be referred to as a second non-contact relay.

The control apparatus 1a is connected to the positive electrode P100 of the vehicle power supply 2 at one end of the connecting portion 10, and is connected to the negative electrode N100 of the vehicle power supply 2 at another end of the connecting portion 10. Furthermore, the control apparatus 1a is connected to the positive electrode P100 of the vehicle power supply 2 at one end of the connecting portion 11, and is connected to the negative electrode N100 of the vehicle power supply 2 at another end of the connecting portion 11 via the switch 5. The another end of the connecting portion 11 is an INPUT terminal. The switch 5 is an external component one end of which is connected to the another end of the connecting portion 11 of the control apparatus 1a and another end of which is connected to the negative electrode N100 of the vehicle power supply 2. The switch 5 is, for example, an onboard device that receives operation from a crew of a train (not illustrated). Note that the connection point between the Y-capacitors 21 and 22, the connection point between the Y-capacitors 28 and 29, the negative electrode N100 of the vehicle power supply 2, the another end of the connecting portion 10 of the control apparatus 1a, and the another end of the switch 5 are connected to the FG 4.

The inductors 31 and 32 are disposed on the first power supply lines 34 and 35, respectively. Specifically, as illustrated in FIG. 5, the inductor 31 is disposed on the first power supply line 34, and the inductor 32 is disposed on the first power supply line 35. That is, the control apparatus 1a includes the two first power supply lines 34 and 35 on each of which an inductor is disposed. The first power supply lines 34 and 35 on which the inductors 31 and 32 are disposed, respectively, are power supply lines that supply first power from the power supply circuit 20 to the control circuit 33a and a first output end of the photocoupler 52 to which a light-receiving element 52b is connected.

Note that no inductor is disposed on the second power supply lines 36 and 37. That is, the control apparatus 1a includes the two second power supply lines 36 and 37 on which no inductor is disposed. The second power supply lines 36 and 37 are power supply lines that supply second power from the power supply circuit 20 to a first input end of the photocoupler 52 and a second output end of the photocoupler 54. A light-emitting diode 52a is connected to the first input end. A light-receiving element 54b is connected to the second output end.

The control circuit 33a is supplied with the first power from the power supply circuit 20 via the two first power supply lines 34 and 35. The control circuit 33a acquires the information on the operation received by the switch 5.

The resistor 51 is a resistor for adjusting the magnitude of the first power supplied from the power supply circuit 20. The resistor 53 is a resistor for adjusting the magnitude of the second power supplied from the power supply circuit 20. The diode 55 is connected in parallel to the photocoupler 54. The resistor 56 is a resistor for adjusting the magnitude of third power supplied from the vehicle power supply 2.

The photocoupler 52 includes the light-emitting diode 52a and the light-receiving element 52b. In addition, the photocoupler 52 has the first input end and the first output end. The light-emitting diode 52a is connected to the first input end. The light-receiving element 52b is connected to the first output end. As illustrated in FIG. 5, the light-receiving element 52b at the first output end is supplied with the first power from the power supply circuit 20 via the two first power supply lines 34 and 35, and the light-emitting diode 52a at the first input end is supplied with the second power from the power supply circuit 20 via the two second power supply lines 36 and 37.

The photocoupler 54 includes a light-emitting diode 54a and the light-receiving element 54b. In addition, the photocoupler 54 has a second input end and the second output end. The light-emitting diode 54a is connected to the second input end. The light-receiving element 54b is connected to the second output end. As illustrated in FIG. 5, the light-receiving element 54b at the second output end is supplied with the second power from the power supply circuit 20 via the two second power supply lines 36 and 37, and the light-emitting diode 54a at the second input end is supplied with the third power from the vehicle power supply 2, and is connected to the switch 5 serving as an external component.

In the control apparatus 1a of the present embodiment, the third power is conducted to the switch 5 and the light-emitting diode 54a at the second input end of the photocoupler 54 in response to the operation received by the switch 5, so that the light-emitting diode 54a at the second input end of the photocoupler 54 emits light. Therefore, the second power is conducted to the light-receiving element 54b at the second output end of the photocoupler 54. The light-receiving element 54b at the second output end of the photocoupler 54 and the light-emitting diode 52a at the first input end of the photocoupler 52 are connected in series. Thus, in the control apparatus 1a, when the second power is conducted to the light-receiving element 54b at the second output end of the photocoupler 54, the second power is conducted to the light-emitting diode 52a at the first input end of the photocoupler 52. When the second power is conducted to the light-emitting diode 52a at the first input end of the photocoupler 52, the light-emitting diode 52a at the first input end of the photocoupler 52 emits light. Thus, the first power is conducted to the light-receiving element 52b at the first output end of the photocoupler 52. As a result of conduction of the first power to the light-receiving element 52b at the first output end of the photocoupler 52, the first power that can be detected by the control circuit 33a fluctuates. The fluctuations in the first power correspond to fluctuations caused in response to the operation received by the switch 5. Therefore, the control circuit 33a can acquire the information on the operation received by the switch 5 based on the fluctuations in the first power conducted to the light-receiving element 52b at the first output end of the photocoupler 52.

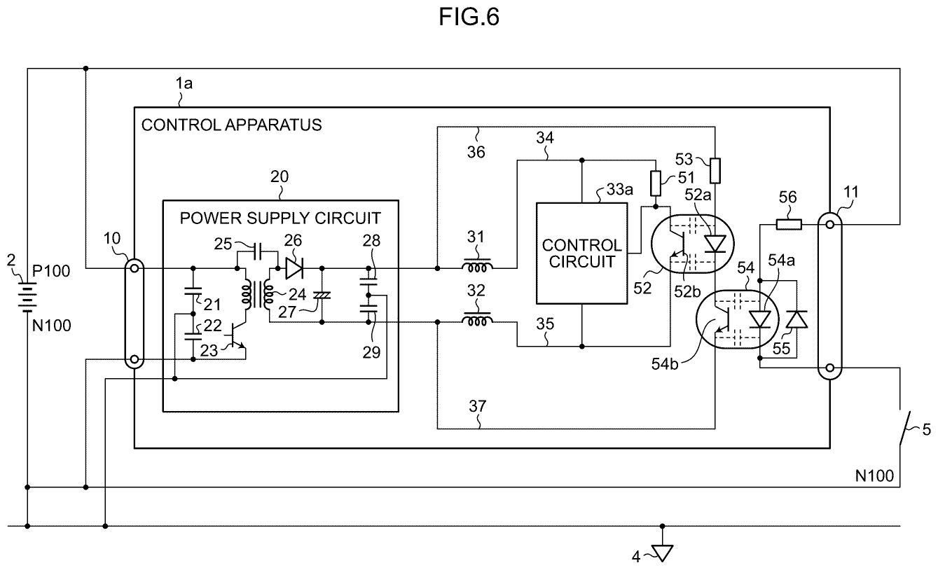

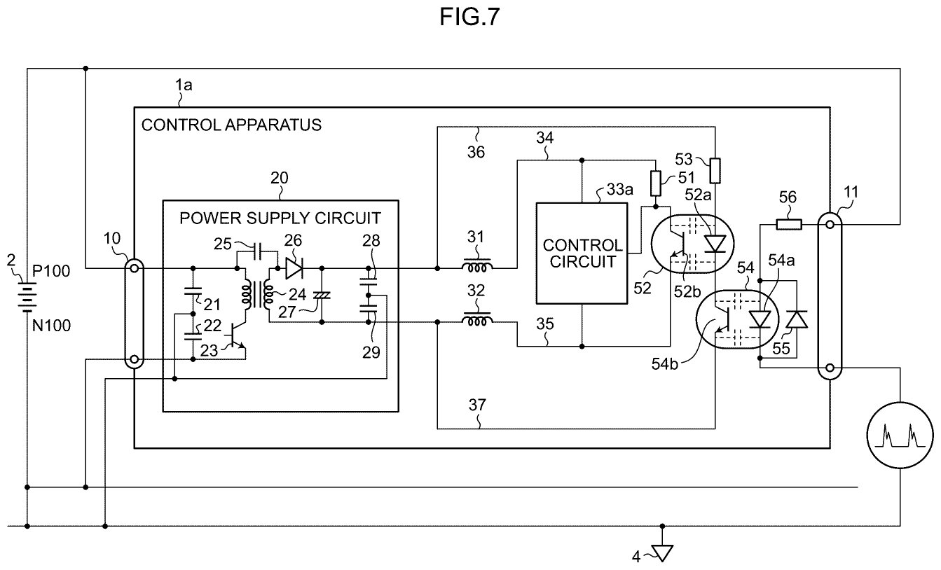

Here, as described in the section “Background”, it is assumed that parasitic capacitances are present inside the photocouplers 52 and 54 and the like. FIG. 6 is a diagram illustrating an image of parasitic capacitances present in the control apparatus 1a according to the second embodiment. The control apparatus 1a illustrated in FIG. 6 is different from the control apparatus 1a illustrated in FIG. 5 in that parasitic capacitances have been added to the inside of the photocouplers 52 and 54. Meanwhile, in fact, a parasitic capacitance is also present between wires, between a wire and a housing, and the like. In a case where parasitic capacitances are present inside the control apparatus 1a as illustrated in FIG. 6, when common-mode noise is generated at the switch 5, that is, when the switch 5 serves as a noise source of common-mode noise, a loop is generated in which common-mode noise flows inside the control apparatus 1a and returns from the FG 4 to the noise source. FIG. 7 is a diagram illustrating an image of a circuit where the switch 5 connected to the control apparatus 1a according to the second embodiment serves as a noise source of common-mode noise. As illustrated in FIG. 7, when the switch 5 serves as a noise source of common-mode noise, the noise source can be regarded as a circuit configuration in which one end is connected to the another end of the connecting portion 11 of the control apparatus la as with the switch 5, but another end is connected to the FG 4. In such a case, when common-mode noise flows to the control circuit 33a, there is a possibility that the control circuit 33a may malfunction and affect acquisition of the information on the operation received by the switch 5.

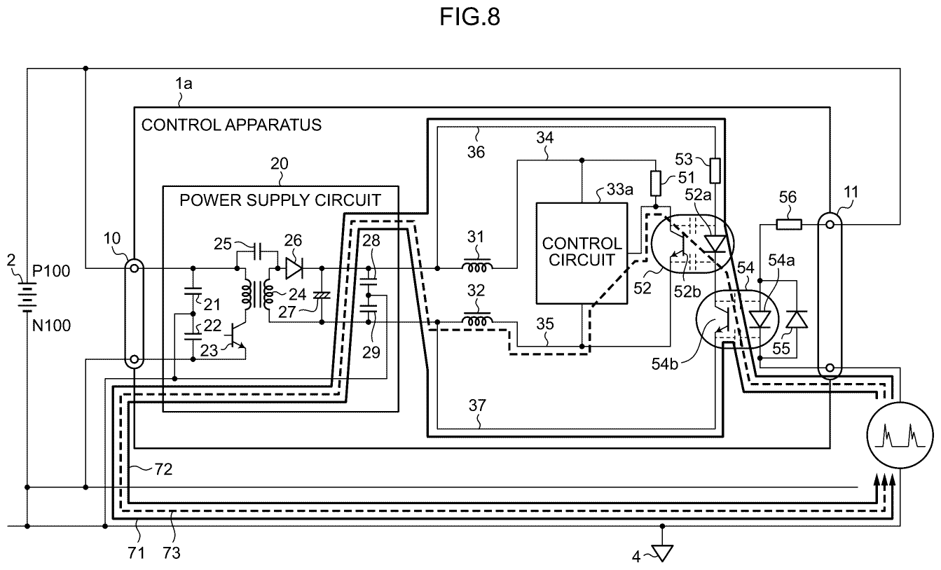

However, in the present embodiment, the inductors 31 and 32 are disposed on the first power supply lines 34 and 35, respectively, through which the first power is supplied from the power supply circuit 20 to the control circuit 33a. Since the inductors 31 and 32 are disposed on the first power supply lines 34 and 35, respectively, impedances of the first power supply lines 34 and 35 are larger than impedances of the second power supply lines 36 and 37 on which no inductor is disposed. Therefore, even in a case where common-mode noise flows inside the control apparatus 1a, more common-mode noise flows through the second power supply lines 36 and 37 having smaller impedances, than through the first power supply lines 34 and 35 to which the control circuit 33a is connected. FIG. 8 is a diagram illustrating exemplary paths 71 to 73 through which common-mode noise flows in the control apparatus 1a according to the second embodiment. The paths 71 to 73 through which common-mode noise flows in the control apparatus 1a have been added to FIG. 7 to obtain FIG. 8. From the relationship between the respective impedances of the power supply lines provided inside the control apparatus 1a as described above, it is considered that most of common-mode noise flows through the paths 71 and 72 and hardly flows through the path 73.

The path 71 is a path from the noise source to the noise source via the connecting portion 11, parasitic capacitances of the photocoupler 54, the light-emitting diode 52a of the photocoupler 52, the resistor 53, the second power supply line 36, the Y-capacitor 28, the connection point between the Y-capacitors 28 and 29, and the FG 4. The path 72 is a path from the noise source to the noise source via the connecting portion 11, a parasitic capacitance of the photocoupler 54, the second power supply line 37, the Y-capacitor 29, the connection point between the Y-capacitors 28 and 29, and the FG 4. The path 73 is a path from the noise source to the noise source via the connecting portion 11, the parasitic capacitances of the photocoupler 54, parasitic capacitances of the photocoupler 52, the control circuit 33a, the first power supply line 35, the inductor 32, the Y-capacitor 29, the connection point between the Y-capacitors 28 and 29, and the FG 4. Note that the path 73 may be a path from the noise source to the noise source via the connecting portion 11, the parasitic capacitances of the photocoupler 54, the parasitic capacitances of the photocoupler 52, the control circuit 33 a, the first power supply line 34, the inductor 31, the Y-capacitor 28, the connection point between the Y-capacitors 28 and 29, and the FG 4. Note that the paths 71 to 73 illustrated in FIG. 8 are examples, and parasitic capacitances may also be present between wires, between a wire and the vehicle body, and the like.

As described above, in a case where common-mode noise flows through the control apparatus 1a where the switch 5 serves as a noise source, a total amount of common-mode noise flowing through the two second power supply lines 36 and 37 is larger than a total amount of common-mode noise flowing through the two first power Supply lines 34 and 35.

Note that, in the present embodiment, the photocoupler 52 is used as the first non-contact relay, and the photocoupler 54 is used as the second non-contact relay, but the first non-contact relay and the second non-contact relay are not limited thereto. The control apparatus 1a may use a PhotoMOS relay as each of the first non-contact relay and the second non-contact relay. Alternatively, the control apparatus 1a may use a photocoupler as one of the first non-contact relay and the second non-contact relay and use a PhotoMOS relay as the other of the first non-contact relay and the second non-contact relay. In addition, the control apparatus 1a can also use a mechanical relay as the first non-contact relay and the second non-contact relay. As described above, the control apparatus 1a can use a photocoupler, a PhotoMOS relay, or a mechanical relay as the first non-contact relay and the second non-contact relay.

As described above, according to the present embodiment, the control apparatus 1a supplies the first power from the power supply circuit 20 to the control circuit 33a and the light-receiving element 52b at the first output end of the photocoupler 52 serving as the first non-contact relay via the first power supply line 34, on which the inductor 31 is disposed, and the first power supply line 35, on which the inductor 32 is disposed. In addition, the control apparatus 1a supplies the second power from the power supply circuit 20 to the light-emitting diode 52a at the first input end of the photocoupler 52 serving as the first non-contact relay and to the light-receiving element 54b at the second output end of the photocoupler 54 serving as the second non-contact relay via the second power supply lines 36 and 37. As a result, even when common-mode noise is generated at the switch 5 serving as a noise source and the common-mode noise flows inside the control apparatus 1a, the control apparatus 1a can cause more common-mode noise to flow through the second power supply lines 36 and 37 than through the first power supply lines 34 and 35 to which the control circuit 33a is connected. Thus, malfunction of the control circuit 33a due to common-mode noise can be reduced. That is, while including the non-contact relays, the control apparatus 1a can reduce the inflow of noise into a desired path via a parasitic capacitance, specifically, into the first power supply lines 34 and 35 to which the control circuit 33a is connected.

Here, in the control apparatus 1 of the first embodiment, the first power is supplied to the light-emitting diode 42a at the first input end, and the second power is supplied to the light-receiving element 42b at the first output end, in the photocoupler 42 serving as the first non-contact relay. Furthermore, in the PhotoMOS relay 44 serving as the second non-contact relay, the second power is supplied to the light-emitting diode 44a at the second input end, and the third power is supplied to the light-receiving element 44b at the second output end. Meanwhile, in the control apparatus 1a of the second embodiment, the first power is supplied to the light-receiving element 52b at the first output end, and the second power is supplied to the light-emitting diode 52a at the first input end, in the photocoupler 52 serving as the first non-contact relay. Furthermore, in the photocoupler 54 serving as the second non-contact relay, the second power is supplied to the light-receiving element 54b at the second output end, and the third power is supplied to the light-emitting diode 54a at the second input end.

As described above, the control apparatus 1 of the first embodiment and the control apparatus 1a of the second embodiment are different in electric power to be supplied to the input end and output end of each non-contact relay, but can obtain the same effect as described above. That is, the control apparatuses 1 and 1a just need to include: the first non-contact relay having the first input end and the first output end one of which is supplied with the first power from the power supply circuit 20 via the two first power supply lines 34 and 35 and the other of which is supplied with the second power from the power supply circuit 20 via the two second power supply lines 36 and 37; and the second non-contact relay having the second input end and the second output end one of which is supplied with the second power from the power supply circuit 20 via the two second power supply lines 36 and 37 and the other of which is supplied with the third power, and is connected to an external component.

The configurations set forth in the above embodiments show examples, and it is possible to combine the configurations with another known technique or combine the embodiments with each other, and is also possible to partially omit or change the configurations without departing from the scope of the present disclosure.

### REFERENCE SIGNS LIST

1, 1a control apparatus; 2 vehicle power supply; 3 load; 4 FG; 5 switch; 10, 11 connecting portion; 20 power supply circuit; 21, 22, 28, 29 Y-capacitor; 23 switching element; 24 transformer; 25, 27 capacitor; 26, 55 diode; 31, 32 inductor; 33, 33a control circuit; 34, 35 first power supply line; 36, 37 second power supply line; 41 transistor; 42, 52, 54 photocoupler; 42a, 44a, 52a, 54a light-emitting diode; 42b, 44b, 52b, 54b light-receiving element; 43, 45, 51, 53, 56 resistor; 44 PhotoMOS relay; 61 to 63, 71 to 73 path.

1. A control apparatus comprising:
two first power supply lines, an inductor being disposed on each of the two first power supply lines;
two second power supply lines;
a control circuit to which first power is supplied from a power supply circuit via the two first power supply lines;
a first non-contact relay having a first input end and a first output end, the first power being supplied to one of the first input end and the first output end from the power supply circuit via the two first power supply lines, second power being supplied to another of the first input end and the first output end from the power supply circuit via the two second power supply lines; and
a second non-contact relay having a second input end and a second output end, the second power being supplied to one of the second input end and the second output end from the power supply circuit via the two second power supply lines, third power being supplied to another of the second input end and the second output end, an external component being connected to the another of the second input end and the second output end.

2. The control apparatus according to claim 1, wherein
the external component is a load, and
the control circuit:
is capable of controlling conduction of the first power at the first input end of the first non-contact relay;
causes the second power to be conducted to the first output end of the first non-contact relay by conducting the first power to the first input end of the first non-contact relay;
causes the second power to be conducted to the second input end of the second non-contact relay by conducting the second power to the first output end of the first non-contact relay;
causes the third power to be conducted to the second output end of the second non-contact relay by conducting the second power to the second input end of the second non-contact relay; and
controls operation of the load by conducting the third power to the second output end of the second non-contact relay to cause the third power to be supplied to the load.

3. The control apparatus according to claim 2, wherein
when common-mode noise flows through the control apparatus, the load serving as a noise source of the common-mode noise, a total amount of the common-mode noise flowing through the two second power supply lines is larger than a total amount of the common-mode noise flowing through the two first power supply lines.

4. The control apparatus according to claim 1, wherein
the external component is a switch, and
as a result of conduction of the first power to the first output end of the first non-contact relay, the control circuit acquires information on operation received by the switch, based on fluctuations in the first power conducted to the first output end of the first non-contact relay due to facts that:
when the third power is conducted to the switch and the second input end of the second non-contact relay in response to the operation received by the switch, the second power is conducted to the second output end of the second non-contact relay;
when the second power is conducted to the second output end of the second non-contact relay, the second power is conducted to the first input end of the first non-contact relay; and
when the second power is conducted to the first input end of the first non-contact relay, the first power is conducted to the first output end of the first non-contact relay.

5. The control apparatus according to claim 4, wherein when common-mode noise flows through the control apparatus, the switch serving as a noise source of the common-mode noise, a total amount of the common-mode noise flowing through the two second power supply lines is larger than a total amount of the common-mode noise flowing through the two first power supply lines.

6. The control apparatus according to claim 1, wherein
the first non-contact relay and the second non-contact relay are each a photocoupler, a photo metal-oxide-semiconductor field-effect transistor relay, or a mechanical relay.

7. The control apparatus according to claim 2, wherein
the first non-contact relay and the second non-contact relay are each a photocoupler, a photo metal-oxide-semiconductor field-effect transistor relay, or a mechanical relay.

8. The control apparatus according to claim 3, wherein
the first non-contact relay and the second non-contact relay are each a photocoupler, a photo metal-oxide-semiconductor field-effect transistor relay, or a mechanical relay.

9. The control apparatus according to claim 4, wherein
the first non-contact relay and the second non-contact relay are each a photocoupler, a photo metal-oxide-semiconductor field-effect transistor relay, or a mechanical relay.

10. The control apparatus according to claim 5, wherein
the first non-contact relay and the second non-contact relay are each a photocoupler, a photo metal-oxide-semiconductor field-effect transistor relay, or a mechanical relay.
